(19) United States
(12) Patent Application Publication
(10) Pub. No.: US 2026/0212244 A1
(43) Pub. Date: Jul. 23, 2026

(54) RESONATOR

(71) Applicant: IQM FINLAND OY, Espoo (FI)

(72) Inventor: Eelis TAKALA, Espoo (FI)

(21) Appl. No.: 19/141,587

(22) PCT Filed: Dec. 21, 2022
(86) PCT No.: PCT/FI2022/050860

§ 371 Date: Jun. 20, 2025

(51) Int. Cl. G06N 10/40; H03K 17/92

(52) U.S. Cl. CPC G06N 10/40; H03K 17/92

(57) ABSTRACT

A quantum processing circuit comprising a substrate and one or more resonators on the substrate. The one or more resonators comprise a set of two or more conducting traces on the surface of the substrate, and all traces are substantially parallel to each other. Separation gaps extend from each trace to the adjacent trace throughout a resonator region.

### FIELD OF THE DISCLOSURE

This disclosure relates to quantum processing circuits, and more particularly to resonators in such circuits.

### BACKGROUND OF THE DISCLOSURE

Electric resonators are widely used in quantum processing circuits. Qubits which resonate at microwave frequencies are the basic building block of quantum computers. Qubits can also be coupled to signal transmission lines, so that qubit control and readout can be performed through electric signals which resonate in these transmission lines.

Transmission lines and qubits can be formed from traces of superconducting material which form a waveguide on a substrate. FIG. 1a illustrates a co-planar waveguide resonator on the surface of a substrate 15. A layer of superconducting material has been deposited on the substrate. Gaps 14 have been etched through the superconducting material to divide the superconducting layer into multiple regions. Regions 161 and 162 are grounding regions which are connected to ground potential. They may cover a large area to the left and to the right of the illustrated area.

Region 11 is a trace of superconducting material. The trace 11, gaps 14 and grounds 161, 162 form a coplanar waveguide on the surface of the substrate 15. FIG. 1b illustrates a device where trace 12, together with grounding regions 162 and 163 and gaps 14, forms a second coplanar waveguide on the surface of the substrate. FIG. 1c illustrates the waveguides in the xy-plane.

Quantum processing circuits often comprise multiple resonators, and it is often preferable to place them close to each other to minimize the surface area which the circuit requires. However, a general challenge in using tightly packed resonators is that the voltage of a signal oscillating in one resonator can become coupled to the adjacent resonator and cause unwanted disturbances. It would be preferable to avoid this crosstalk.

### BRIEF DESCRIPTION OF THE DISCLOSURE

An object of the present disclosure is to overcome the above disadvantage. The object of the disclosure is achieved by an arrangement which is characterized by what is stated in the independent claims. The preferred embodiments of the disclosure are disclosed in the dependent claims.

The disclosure is based on the idea of removing the central grounding strip between adjacent traces. It has been discovered that, when traces are prepared in this way with a suitable geometry, the traces support uncoupled modes at the resonance frequency.

### BRIEF DESCRIPTION OF THE DRAWINGS

In the following the disclosure will be described in greater detail by means of preferred embodiments with reference to the accompanying drawings, in which

FIGS. 1a-1c illustrate coplanar waveguides known from the prior art.

FIGS. 2a-2b illustrate a surface embodiment.

FIGS. 3a-3c illustrate a surface embodiment where conducting traces are flanked by grounding regions.

FIG. 3d illustrates an insulating layer which fills the separation gap.

FIGS. 3e-3f illustrate an embodiment with three traces.

FIG. 4a illustrates a readout resonator and a transmission line coupled to a qubit.

FIG. 4b illustrates a Josephson junction arranged on a resonator.

FIGS. 5a-5c illustrate traces with turns.

FIG. 5d illustrates a meander pattern and spiral patterns.

FIG. 5e illustrates six parallel traces in the resonator region.

FIGS. 5f-5i illustrate interconnected traces.

FIGS. 6a-6b illustrate a stack embodiment.

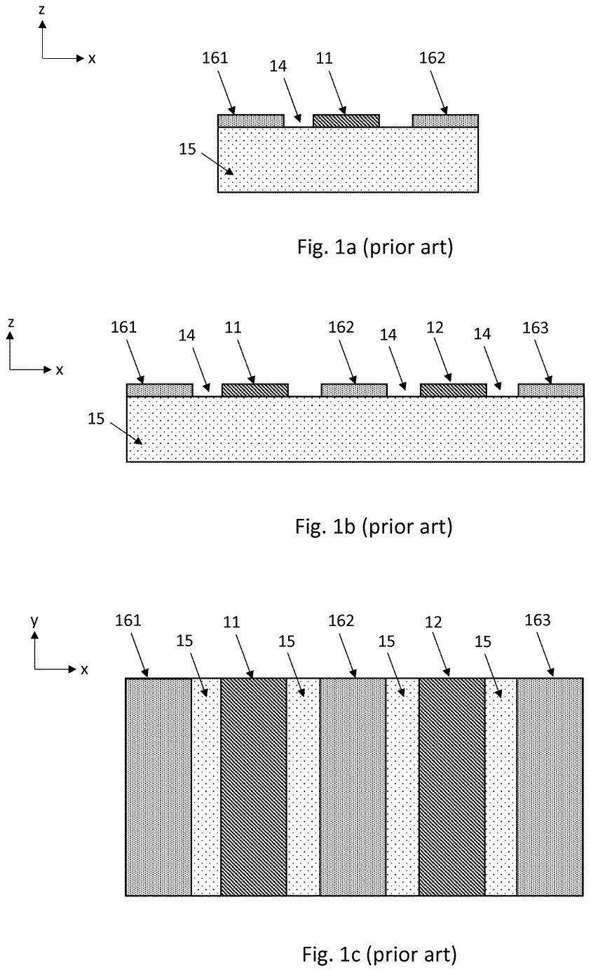

### DETAILED DESCRIPTION OF THE DISCLOSURE

### Surface Embodiment

This disclosure presents a quantum processing circuit comprising a substrate and a set of two or more conducting traces on the surface of the substrate. Each trace in the set of two or more traces comprises an elongated strip of conducting material. The quantum processing circuit comprises a resonator region on the substrate. All traces in the set of two or more traces extend through the resonator region and are substantially parallel to each other in the resonator region. The quantum processing circuit comprises one or more separation gaps. Each separation gap extends from one trace in the set of two or more traces to the adjacent trace in the set of two or more traces throughout the resonator region.

A quantum computer may comprise any quantum processing circuit presented in this disclosure.

The words “conducting” and “conductive” refer in this disclosure to electrical conductance. In any embodiment presented in this disclosure, the quantum processing circuit may be, but does not have to be, a superconducting circuit. The traces may be superconducting in any embodiment.

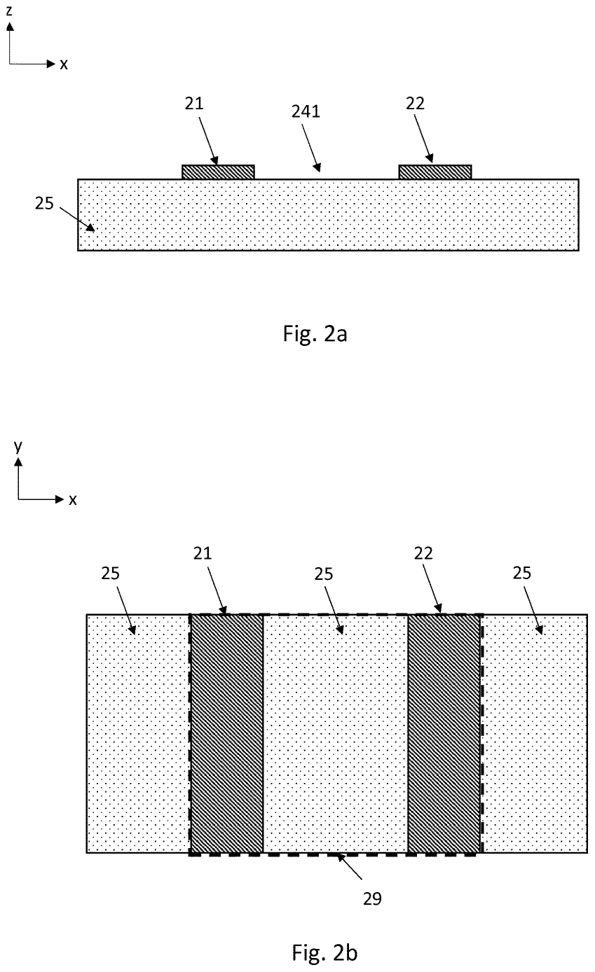

FIG. 2a illustrates a substrate 25 and two conducting traces 21 and 22 on the substrate. In any embodiment of this disclosure, the substrate may define an xy-plane and a z-direction which is perpendicular to the substrate. FIG. 2b illustrates the substrate 25 in the xy-plane. The traces are parallel to each other in a resonator region 29. They may extend beyond this region in the y-direction in FIG. 2b (this has not been illustrated), and the two traces may diverge from each other outside of the resonator region 29. In this region, the traces 21 and 22 are separated by a separation gap 241 which fills the area between the two traces 21 and 22 in the resonator region 29. In other words, no electrically conductive element lies between the first trace 21 and the second trace 22 in this region. The resonator region 29 is delimited by the outermost traces.

The quantum processing circuit may be formed on a substrate which has a layer of conducting material on top of the substrate. The circuit may comprise a set of gaps which extend through the layer of conducting material and delimit the set of two or more traces on the substrate. The set of gaps may comprise the one or more separation gaps.

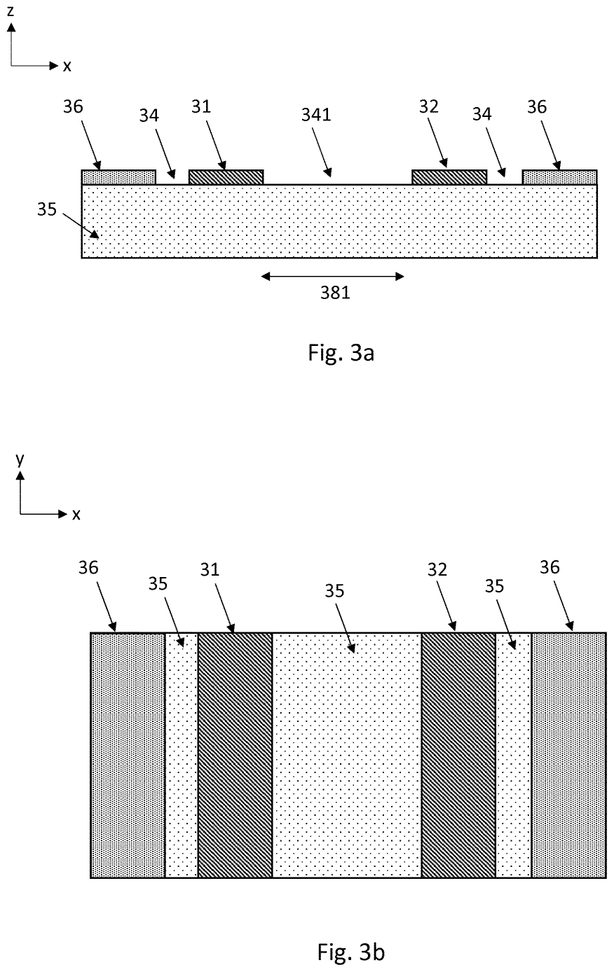

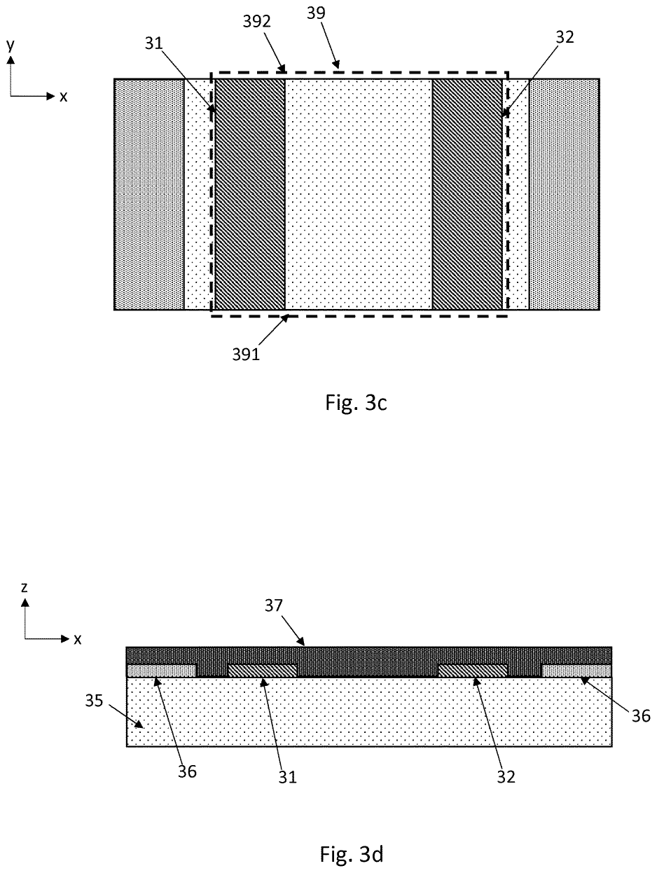

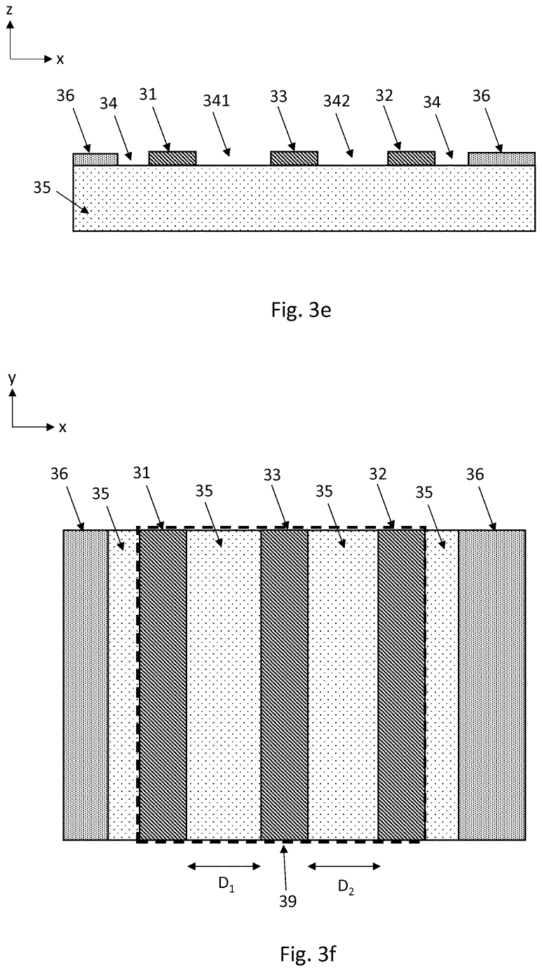

FIG. 3a illustrates an embodiment where the quantum processing circuit comprises a substrate 35 which defines an xy-plane and a z-direction which is perpendicular to that plane. The xy-plane may be called the substrate plane. A layer of conducting material has been deposited on the substrate 35 and then patterned. Grounding regions 36 and traces 31 and 32 lie on the substrate 35. These traces 31/32 and grounding regions 36 may be formed from the same layer of conducting material. Alternatively, two separate conducting materials could be deposited and patterned on the substrate so that traces 31 and 32 are formed from a first conducting material and the grounding regions 36 from a second conducting material. The conducting material from which the traces 36 and/or grounding regions 31/32 are formed may for example be Nb, Al, TiN, NbN, NbTIN or Ta in any embodiment described in this disclosure.

The quantum processing circuit in FIG. 3a comprises a set of gaps 34, 341 in the layer of conducting material. This set includes boundary gaps 34 which lie between a trace 31/32 and the adjacent grounding region 36. The set also includes a separation gap 341 which separates two adjacent traces 31/32 from each other. FIG. 3b illustrates the traces 31 and 32 and the grounding regions 36 in the xy-plane. Figures such as 3b illustrate only a part of the quantum processing circuit in the xy-plane. The circuit may extend beyond the figure in the x-and y-directions, but these additional parts of the circuit are not illustrated. The substrate 35 is in FIG. 3b visible between the traces 31/32 and the grounding regions 36.

FIG. 3c illustrates a resonator region 39 in the xy-plane. The resonator region 39 is delimited by the traces 31/32 which lie furthest apart from each other. Each trace 31/32 extends through the resonator region 39. Beyond the resonator region the traces 31/32 may be coupled to signal generators, to readout electronics, to qubits or to each other. Within the resonator region 39, each trace 31/32 in the set of two or more traces may be electrically separated from the other traces 31/32 in the set. All traces 31/32 in the set are parallel or substantially parallel to each other in the resonator region 39.

The term “elongated strip” refers in this disclosure to the shape of a trace in the xy-plane. For example, in FIG. 3b the first and second traces 31 and 32 have a width in the x-direction and a length in the y-direction. In some embodiments described below, the traces comprise straight sections and turn sections in the resonator region, so that the trace does not extend through the resonator region in a straight line. The length of the trace in the resonator region may in such cases be calculated from one end of the trace to the other, including the turn. In any embodiment described in this disclosure, the length/width aspect ratio of a trace in the resonator region may for example be greater than 3, greater than 10, greater than 50, greater than 100 or greater than 1000.

The term “resonator” refers in this disclosure to a conducting trace (or a combination of multiple concatenated traces) with a finite length L. The trace has a first end and a second end. The length L is measured from the first end to the second end along the trace. Either end of the trace may terminate for example in a large gap to adjacent structures (open circuit) or in a galvanic contact to ground (short circuit). Either end may alternatively be connected to a device, for example a qubit or a transmission line, directly or via capacitive contact. An electromagnetic signal may resonate as a standing wave in a resonator. In most quantum computing applications and other superconducting circuit applications the signal wavelengths are in the millimeter-centimeter range. Consequently, the length L of any resonator described in this disclosure may for example be in the range 1 mm-100 cm, or 1 mm-10 cm, or 1 mm-10 mm. However, other lengths are also possible.

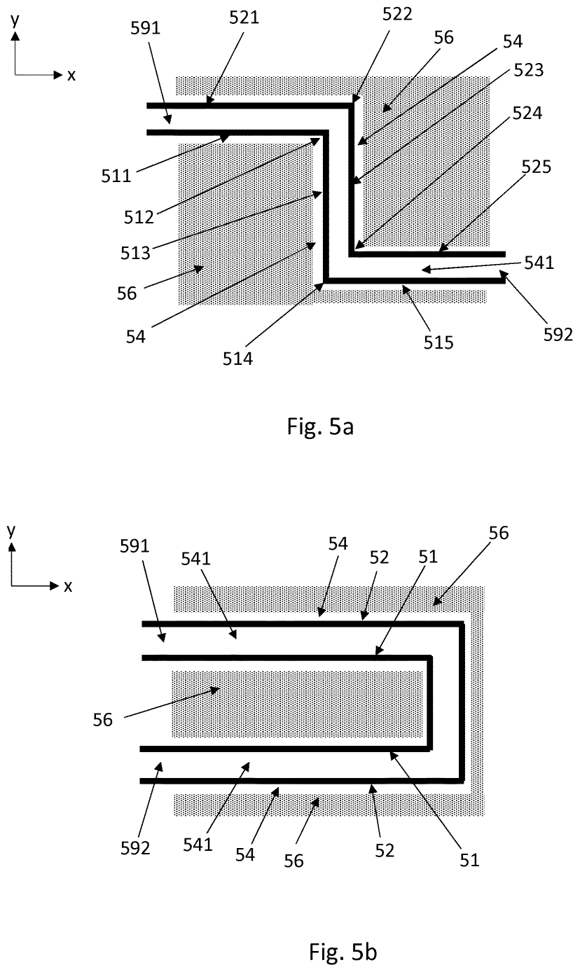

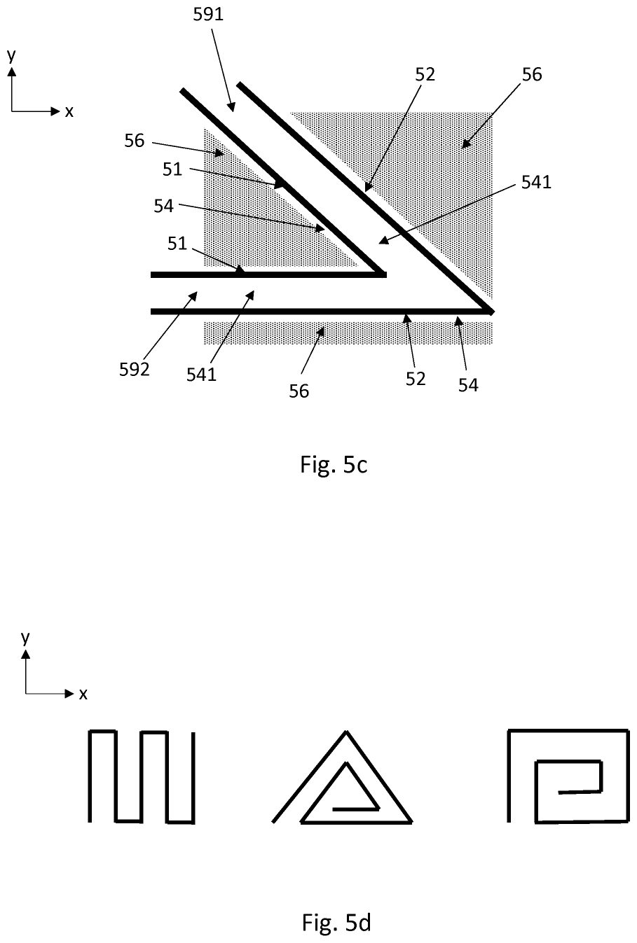

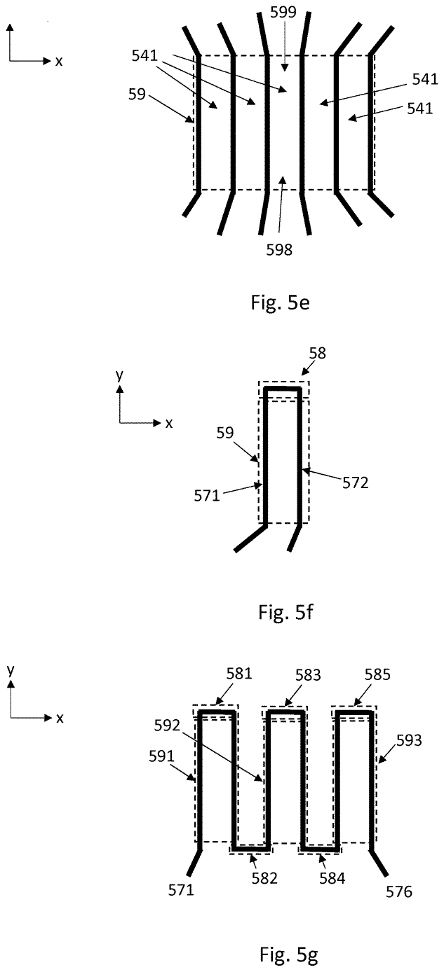

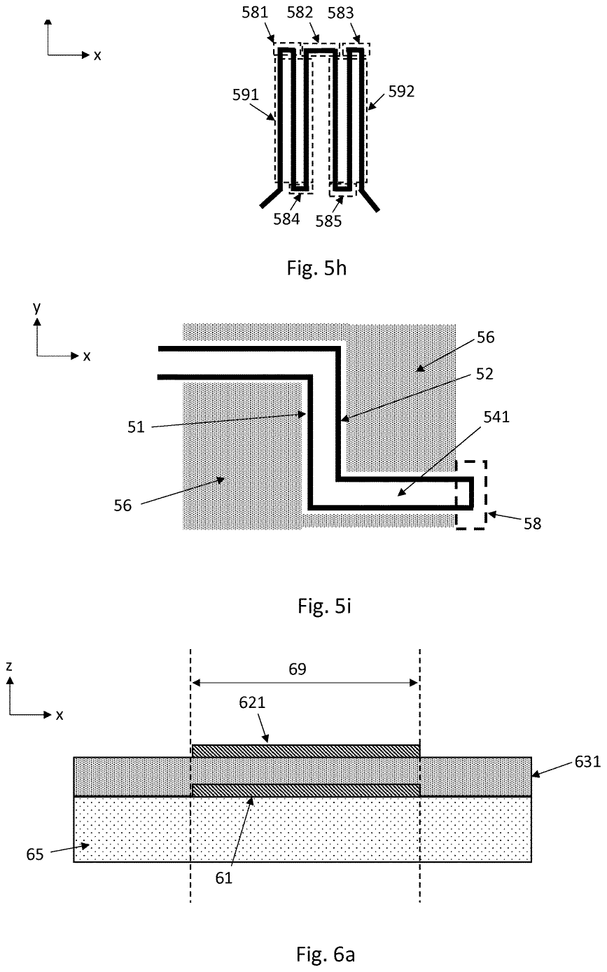

The term “separation gap” refers in this disclosure to an area of the substrate where no conductive material, or very little conductive material, is present. It can be seen in FIGS. 3a-3c that the separation gap 341 extends between the first trace 31 and the second trace 32 throughout the resonator region 39. In other words, the separation gap 341 occupies all of the surface area between the first trace 31 and the second trace 32 within the resonator region 39. This means in FIG. 3c that the first and second traces 31 and 32 extend from a first side 391 of the resonator region to a second side 392 of the resonator region, and the separation gap also extends all the way from the first side 391 to the second side 392. The first side and second sides do not necessarily have to be geometrically opposite to each other. This is illustrated for example in FIGS. 5a-5c. The considerations presented in this paragraph apply to all embodiments presented in this disclosure.

There is no grounding region or other region of conductive material between the first and second traces. The traces and the separation gap between them can be formed by depositing a layer of conducting material on the substrate and then etching away this material from the area where the separation gap should be. The trench which forms the gap may in practice extend into the substrate in the z-direction, but this has not been illustrated in the figures.

It may in some embodiments be possible for the resonators to retain independent voltage signals even if a small, electrically floating island of electrically conductive material lies somewhere inside the separation gap. However, for the sake of simplicity, the following discussion will assume that the separation gaps occupy the area between adjacent traces in full.

The one or more separation gaps may be empty cavities, so that the surrounding gas atmosphere fills the separation gaps. This is illustrated in FIG. 3d. The gas atmosphere may be a vacuum or filled with gas. Alternatively, the separation gap may be filled with an insulating layer 37, as FIG. 3d illustrates. The insulating layer may lie only between adjacent traces, or only in the resonator region. Alternatively, as FIG. 3d illustrates, the insulating layer 37 may extend to the grounding regions 36 and cover these regions. These alternatives apply to all surface embodiments.

The width 381 (illustrated in FIG. 3a) of any separation gap is the distance between two adjacent traces in the resonator region. The width 381 may for example be in the range 1 μm-100 μm, or in the range 1 μm-20 μm.

FIGS. 3e-3f illustrate an embodiment where the two or more traces comprise three traces 31-33. In any embodiment of this disclosure where there are more than two traces, the traces may be placed so that each trace (for example 33 in FIG. 3f) lies at a distance D₁ from the neighbouring trace (31) which is adjacent on a first side (for example in the x-direction in the surface embodiment, or in the z-direction in the stack embodiment) and at a distance D₂ from the adjacent trace (32) on a second side which is opposite to the first side. D₁ may be equal to D₂. D₁ and D₂ may then obtain values in any of the ranges listed above. Alternatively, D₁ and D₂ may be unequal. D₁ may then obtain values in any of the ranges listed above, and the relationship D₁/D₂ may for example be greater than 2, greater than 4 or greater than 10. The width of any trace described in this disclosure may for example be in the range 1 μm-100 μm, or in the range 1 μm-20 μm.

The gaps in FIG. 3e comprise boundary gaps 34, which lie just outside of the resonator region 39. In other words, the boundary gaps lie on the outer side of the outermost traces, which are traces 31 and 32 in this case. The gaps also comprise a first separation gap 341 between a first trace 31 and a third trace 33, and a second separation gap 342 between a second trace 32 and the third trace 33.

The two or more traces may alternatively comprise four, five, six, seven, eight, nine, ten, or more than traces. The number of independent resonators may, but does not necessarily have to be, equal to the number of traces. This will be explained in more detail below.

Regardless of the number of traces, the outermost traces, which are closest to the opposing edges of the resonator region (in the x-direction), may be flanked by grounding regions 36, as traces 31 and 32 are in FIGS. 3a-3f. The outermost traces may be called edge traces. The other traces, such as 33, may be called central traces. Each central trace (33) is flanked by two other traces (in this case 31 and 32). Each edge trace (for example 31) is therefore adjacent to a grounding region 36 on one side and to another trace 33 on the other side with a boundary gap 34 and separation gap 341 in between, and each central trace (for example 33) is adjacent to one trace (31) on one side and to another trace (32) on the other side with a separation gap 341/342 on both sides.

In any embodiment presented in this disclosure the set of two or more traces may throughout the resonator region be flanked on one side or on both sides of the resonator region by one or more layers of conducting material which are at ground potential. The edges of these grounding regions may be parallel or approximately parallel to the traces. This means (using FIG. 3e as an example) that the boundary gap 34 has the same width (in the x-direction) all the way along the resonator region. The boundary gap 34 is therefore also parallel to the traces 31-33.

Alternatively, the set of two or more traces may be flanked on one or both sides of the resonator region by an insulating material. Throughout this disclosure, region A is flanked by region B if region B is situated at the side of region A. Region A may have a complex shape, but the edge of region B lies at the side of the edge of region A in every location where region B flanks region A.

Parallel traces as presented in this disclosure have a unique property of uncoupled modes at their resonance frequency. This follows from telegrapher's equations for multi-transmission lines for which the resulting propagation matrix is like the identity matrix but multiplied with a scalar. This means that any mode is an eigenmode of the system and thus are the single trace modes that we call uncoupled. The solution assumes that the capacitance matrix is describable from the capacitance matrix without dielectrics (C₀) multiplied by a scalar and the inductance matrix can be computed from L=εμC₀⁻¹, where ε is electric permittivity and u is magnetic permeability. Even if the assumptions presented here are not exactly followed, the property may still be achieved in practise.

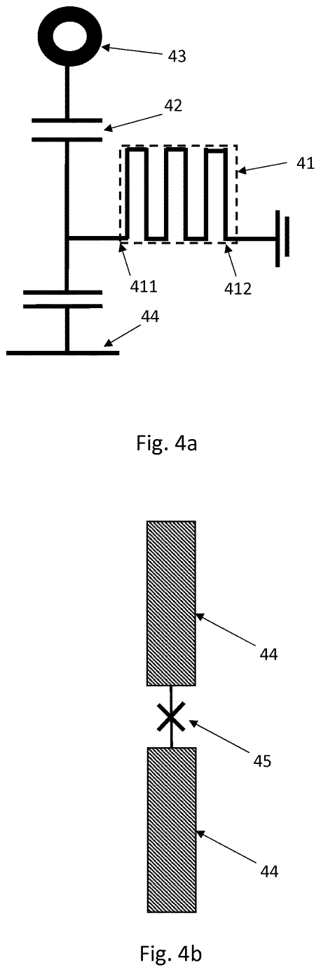

A resonator described in any embodiment of this disclosure may be an input or output transmission line for a qubit. As described in more detail below, one trace may form one resonator. Alternatively, two or more traces may be electrically connected to each other so that they form a single resonator. In either case, the operation of a resonator as a transmission line or readout resonator has been illustrated in FIG. 4a, where 43 is a qubit and 42 is a capacitive coupling between the qubit 43 and a readout resonator 41. The figure also illustrates a readout transmission line 44. The resonator 41 or the transmission line 44 may be formed by one (or many) of the two or more traces discussed in this disclosure. Resonators coupled to other qubits may be adjacent to the illustrated resonator 41. The resonator 41 receives at its first end 411 as input a signal from the qubit 43 and outputs the readout signal at its second end 412.

In any embodiment described in this disclosure, the quantum processing circuit may comprise one or more signal transmitters which are coupled to the set of two or more traces and configured to transmit one or more high-frequency electromagnetic waves to the two or more traces so that said electromagnetic waves obtain electrical resonance in said traces. Alternatively, or complementarily, the quantum processing circuit may comprise one or more signal detectors which are coupled to the set of two or more traces and configured to detect the resonance state of the two or more traces.

Alternatively, any resonator described in any embodiment of this disclosure may itself be used as a qubit. One or more Josephson junctions may in this case be embedded in the resonator. This is illustrated in FIG. 4b, where a Josephson junction 45 has been arranged on resonator 44. The resonator 44 may serve as a linear inductive-energy element in the qubit, while the Josephson junction which is embedded in the resonator serves as a non-linear inductive-energy element. Resonators which form other qubits, or which are coupled to other qubits, may be adjacent to the illustrated resonator 44.

In any embodiment presented in this disclosure, each trace in the set of two or more traces may comprise two or more straight sections and a turn section between each pair of consecutive straight sections. FIG. 5a illustrates a resonator region. Reference numbers 54, 56 and 541 correspond to reference numbers 34, 36 and 341, respectively, in FIGS. 3a-3d. In FIG. 5a and in all other surface embodiments, the resonator region lies between the boundary gaps 54.

First and second traces are in FIG. 5a illustrated simply as black lines. The first trace comprises straight sections 511 and 515 and turn sections 512-514 which lie between the straight sections. The second trace comprises straight sections 521 and 525 and turn sections 522-524 which lie between the straight sections. Each turn sections constitute two 90-degree turn in the xy-plane which shift the traces in the y-direction.

The two or more straight sections may comprise at least two straight sections, and the angle between each pair of consecutive straight sections may be substantially 180 degrees. One 180 degree turn between two consecutive straight sections is illustrated in FIG. 5b, where 51 is the first trace and 52 the second trace. In this geometry, the set of two or more traces may have a meandering shape.

FIG. 5c indicates an alternative geometry where the two or more straight sections comprise at least three straight sections, and the angle between each pair of consecutive straight sections is less than 90 degrees, and the set of two or more traces has a triangular shape. One turn has been illustrated. A further alternative is that the angle may be 90 degrees and the two or more traces may form a rectangular shape.

The set of two or more traces may have a spiral shape. In FIG. 5d, the set of two or more traces and the separation gaps between them are illustrated with a single black line. The figure on the left illustrates a meandering shape. The meander may have any number of turns and straight sections. The figure in the middle illustrates a triangular spiral shape and the figure on the right illustrates a rectangular shape. The spiral could alternatively have a circular shape, or any irregular shape where the traces extend outward from and around a central point. Shapes can also be combined, so that a set of two or more traces forms a meander in a first part of the resonator region and a spiral in a second part of the resonator region.

In any embodiment of this disclosure, the two or more traces may be electrically isolated from each other, so that each trace operates as an independent resonator. In FIG. 5e, each trace is illustrated with its own black line. The resonator region 59, where the traces are parallel to each other, is illustrated. Throughout the resonator region, each pair of adjacent traces are separated from each other by a separation gap 541. In other words, each separation gap 541 occupies all of the surface area between a pair of adjacent traces within the resonator region 59. The two or more traces extend from a first side 598 of the resonator region 59 to a second side 599, and each separation gap also extends from the first side 598 to the second side 599.

The six traces illustrated in the figure are parallel to each other in the resonator region 59, but they diverge from each other outside of the resonator region. They form six resonators. A first end of each trace may be used for resonator input and the second end for resonator output. The quantum processing circuit may in this case for example comprise six qubits, and each trace may be dedicated to a specific qubit. The traces may be used as transmission lines for their respective qubits. The arrangement illustrated in FIG. 5e allows the transmission lines to be packed close to each other in a given area of the substrate surface (the resonator region) without risk of crosstalk. The set of two or more traces may for example form a signal bus in a quantum processor. The resonators formed by the traces can transmit voltage signals independent of each other. Consequently, the bus can transmit multiple signals through a quantum circuit while occupying a small area on the surface of the substrate.

Somewhere beyond the end point of the bus where the traces diverge from their parallel geometry, the ends of all traces may be coupled to a suitable impedance to minimize crosstalk after the point of divergence. In other words, the ends of the traces may be emulated with impedances which minimize signal coupling between the two or more traces outside of the resonator region where they are fully parallel.

The proportion of the length of each trace which lies within the resonator region 59 may be significantly longer than the proportion which lies outside of the resonator region. In other words, the part of the length of each trace which lies within the resonator region may for example more than 90%, more than 95% or more than 99% of the total length of the trace. These options apply to all embodiments presented in this disclosure.

In any embodiment of this disclosure, including the stack embodiment presented below, two traces in the set of two or more traces may be electrically connected to each other outside of the resonator region. In other words, the quantum processing circuit may comprise an interconnection region on the substrate. The interconnection region may lie outside of the resonator region and adjacent to the resonator region. At least two traces in the set of two or more traces may be connected to each other in the interconnection region.

FIG. 5f illustrates an arrangement where an interconnection region 58 lies adjacent to the resonator region 59. The two traces 571 and 572 are connected to each other in the interconnection region, so that they now together form a single resonator. The end of trace 571 may be used for input, and the end of trace 572 for output. Two adjacent traces may, in any embodiment presented in this disclosure and regardless of the shape of the resonator region, be connected to each other in this manner so that they form a single resonator.

In practice, the arrangement shown in FIG. 5f allows the length of the resonator in the y-direction to be halved. If, for example, the length of the resonator should be L=λ/2 in order to obtain a standing resonating wave, where λ is the wavelength of an electromagnetic signal, then the length of the traces 571 and 572 in FIG. 5f only needs to be L/2 in the y-direction (minus the lengths of the interconnections).

Alternatively, as FIG. 5g illustrates, the ends of multiple adjacent traces may be connected to each other so that the connected traces are concatenated into a single resonator. The arrangement in FIG. 5g comprises three resonator regions 591-593, and five interconnection regions 581-585 where the traces in these resonator regions are connected to each other.

The area between resonator regions 591 and 592 and the area between resonator regions 592 and 593 may be grounded. In other words, there may be boundary gaps which. In other words, the opposing sides (in the x-direction) of each resonator region 591-593 may be flanked by grounding regions, and these grounding regions may be separated from the adjacent trace by a boundary gap, as in FIGS. 3a-3f. Resonator region 591 may also be flanked by a grounding region on the left side, and resonator region 593 may be flanked by a grounding region on the right side. Interconnection regions 581, 583 and 585 may similarly be flanked by grounding regions on their top side in FIG. 5g, and interconnection region 582 and 584 on their bottom side.

The resonator may alternatively be implemented without any grounding regions at all. Each region mentioned in the previous paragraph may for example be flanked by an insulating region, or the area between resonator regions 591 and 592 and the area between resonator regions 592 and 593 may simply comprise two gaps which are not filled with any material.

The distance between adjacent traces does not necessarily have to be equal, as in FIG. 5g. The widths of resonator regions 591-593 in the x-direction could for example be narrower than the distances between these resonator regions 591-593 in the x-direction. In other words, interconnection regions 582 and 584 may be wider in the x-direction than interconnection regions 581, 583 and 585. This applies also to FIG. 5h.

In general, multiple resonator regions may be arranged next to each other in the xy-plane, the traces which lie within the same resonator region may be concatenated (in regions 581-583), and traces from adjacent resonator regions may be interconnected (in regions 582 and 584) so that the resonators formed in each resonator region are also concatenated. Optionally, the areas between the resonator regions may be grounding regions. All resonator regions and interconnection regions may optionally be flanked by grounding regions.

The length required for achieving resonance for a given wavelength may thereby be reduced by a factor which equals the number of concatenated traces. FIG. 5h illustrates an alternative arrangement where the resonator in each resonator region 591 and 592 includes three traces. The traces within each resonator region are interconnected in interconnection regions 581, 583, 584 and 585, while the two resonators are interconnected in interconnection region 582. The area between the resonator regions 591 and 592 may be a grounding region.

It should be emphasized that the meandering arrangement illustrated in FIG. 5g, where parallel traces have been concatenated into a single resonator, differs from the arrangements illustrated in FIG. 5d. Each black line in FIG. 5g illustrates a trace. In FIG. 5d, on the other hand, the single black line illustrates the set of two or more parallel traces and the separation gaps between them. The pattern shown in FIG. 5d illustrates the geometry that the resonators could have within the resonator region, while FIG. 5g illustrates how traces can be connected to each other just outside of the resonator region. Consequently, a linear arrangement of traces is used only as an example in FIG. 5e-5h. The traces could be arranged in any regular or irregular geometric pattern in the resonator region (as long as they are parallel to each other) and still be connected to each other. This has been illustrated in FIG. 5i, where an interconnection has been made in interconnection region 58 between the traces that were previously illustrated in FIG. 5a. The interconnections can also be made if the resonator pattern is for example one of the meandering or spiral patterns shown in FIG. 5d.

### Stack Embodiment

This disclosure also describes a quantum processing circuit comprising a substrate and one or more resonators on the substrate. The one or more resonators comprise a conducting first trace on the surface of the substrate. The first trace comprises an elongated strip of conducting material. The quantum processing circuit comprises a resonator region on the substrate The one or more resonators also comprise one or more conducting additional traces and one or more insulating layers stacked on top of the first trace. Each of the one or more additional traces is separated from the underlying trace by one of the one or more insulating layers. Each of the one or more additional traces comprises an elongated strip of conducting material which is aligned on top of the underlying trace throughout the resonator region.

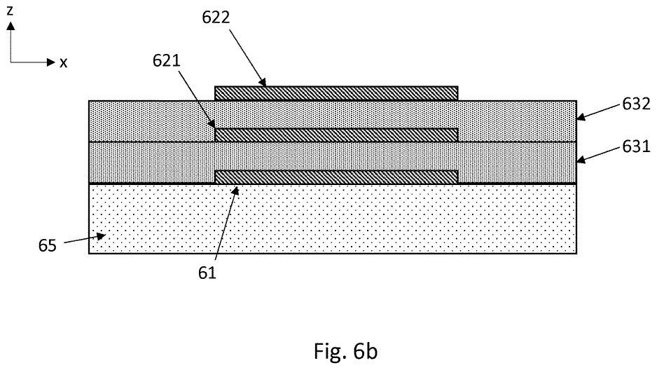

FIG. 6a illustrates a first trace 61 on a substrate 65. The trace 61 is covered by a first insulating layer 631. A first additional trace 621 has then been stacked directly on top of the first trace 61. The first trace 61 may be connected to the first additional trace 621 with a vertical conducting interconnection somewhere in the xy-plane. The location of this interconnection may be called the interconnection region, as in the previous examples. The first trace is connected to the first additional trace 621, then the two traces form a single resonator. If the first trace is electrically separated from the first additional trace, the two traces form two separate resonators.

The resonator region 69 is in this case defined by the position of the stack on the substrate, and its width is determined by the width of the first trace 61. The one or more additional traces all lie on top of the first trace 61 so that they are fully aligned in the z-direction. All of the additional traces are therefore parallel to the first trace 61 in the resonator region 69. FIG. 6b illustrates a stack where a second insulating layer 632 has been placed over the first additional trace 621, and a second additional trace 622 has been placed over the second insulating layer 632.

Interconnections can be made between any pair of adjacent traces in the stack. The stack can be made higher by increasing the number of insulating layers and additional traces as needed. Furthermore, all geometry options that were discussed with reference to FIGS. 5a-5d are applicable to this embodiment as well. The stack of traces may have a linear, meandering or spiral shape on surface of the substrate 65, or any irregular shape.

1. A quantum processing circuit comprising a substrate and one or more resonators on the substrate, wherein the one or more resonators comprise a set of two or more conducting traces on a surface of the substrate, wherein each trace in the set of two or more traces comprises an elongated strip of conducting material,
and the circuit comprises a resonator region on the substrate, and all traces in the set of two or more traces extend through the resonator region and are substantially parallel to each other in the resonator region,
wherein the one or more resonators also comprise one or more separation gaps, and each separation gap extends from one trace in the set of two or more traces to the adjacent trace in the set of two or more traces throughout the resonator region.

2. A quantum processing circuit according to claim 1, wherein the one or more separation gaps are empty cavities, so that the surrounding gas atmosphere fills the separation gaps.

3. A quantum processing circuit according to claim 1, wherein the set of two or more traces is throughout the resonator region flanked on both sides by one or more parts of the layer of conducting material which are at ground potential.

4. A quantum processing circuit according to claim 1, wherein the set of two or more traces have a meandering shape.

5. A quantum processing circuit according to claim 1, wherein the set of two or more traces have a spiral shape.

6. A quantum processing circuit according to claim 1, wherein the circuit also comprises an interconnection region on the substrate, and the interconnection region lies outside of the resonator region and adjacent to the resonator region, and at least two traces in the set of two or more traces are connected to each other in the interconnection region.

7. A quantum processing circuit comprising a substrate and one or more resonators on the substrate, wherein the one or more resonators comprise a conducting first trace on a surface of the substrate, wherein the first trace comprises an elongated strip of conducting material, and the quantum processing circuit comprises a resonator region on the substrate,
wherein the one or more resonators also comprise one or more conducting additional traces and one or more insulating layers stacked on top of the first trace so that each of the one or more additional traces is separated from the underlying trace by one of the one or more insulating layers, and each of the one or more additional traces comprises an elongated strip of conducting material which is aligned on top of the underlying trace throughout the resonator region.

8. A quantum computer comprising a quantum processing circuit according to claim 1.
